(19) United States
(12) Patent Application Publication
(10) Pub. No.: US 2013/0137219 A1
(43) Pub. Date: May 30, 2013

(54) METHOD FOR PRODUCING SEMICONDUCTOR DEVICE

(71) Applicant: NITTO DENKO CORPORATION, Osaka (JP)

(72) Inventors: Hiroyuki Senzai, Ibaraki-shi (JP); Naohide Takamoto, Ibaraki-shi (JP); Kosuke Morita, Ibaraki-shi (JP)

(73) Assignee: NITTO DENKO CORPORATION, Osaka (JP)

(21) Appl. No.: 13/686,852

(22) Filed: Nov. 27, 2012

(30) Foreign Application Priority Data
Nov. 28, 2011 (JP) 2011-259126
Nov. 28, 2011 (JP) 2011-259132

(51) Int. Cl. H01L 21/78

(52) U.S. Cl. CPC H01L 21/78
USPC 438/113

(57) ABSTRACT

There is provided a method for producing a semiconductor device, which is capable of suppressing voids during mounting of a semiconductor element to produce a semiconductor device with high reliability. A method for producing a semiconductor device of the present invention includes the steps of: providing a sealing sheet having a base material and an under-fill material laminated on the base material; bonding the sealing sheet to a surface of a semiconductor wafer on which a connection member is formed; dicing the semiconductor wafer to form a semiconductor element with the under-fill material; retaining the semiconductor element with the under-fill material at 100 to 200° C. for 1 second or more; and electrically connecting the semiconductor element and the adherend through the connection member while filling a space between the adherend and the semiconductor element with the under-fill material.

### BACKGROUND OF THE INVENTION

1. Field of the Invention

The present invention relates to a method for producing a semiconductor device.

2. Description of the Related Art

In recent years, demands for high-density mounting have been increased as electronic instruments have become smaller and thinner. Accordingly, for semiconductor packages, the surface mount type has become mainstream suitable for high-density mounting in place of the conventional pin insertion type. In the surface mount type, a lead is soldered directly to a printed board or the like. For a heating method, the whole of a package is heated by infrared reflow, vapor phase reflow, solder dip or the like to perform mounting.

After surface mounting, a sealing resin is filled in a space between a semiconductor element and a substrate for ensuring protection of the surface of the semiconductor element and connection reliability between the semiconductor element and the substrate. As this sealing resin, a liquid sealing resin is widely used, but it is difficult to adjust an injection position and an injection amount with the liquid sealing resin. Thus, there has been proposed a technique of filling a space between a semiconductor element and a substrate using a sheet-like sealing resin (JP-B1-4438973).

Generally, for a process using a sheet-like sealing resin, such a procedure is employed that a sheet-like sealing resin is attached to a semiconductor wafer, the semiconductor wafer is then diced to form a semiconductor element, and a space between an adherend such as a substrate and the semiconductor element is filled with the sheet-like sealing resin integrated with the semiconductor element while connecting the semiconductor element to the adherend to perform mounting.

### SUMMARY OF THE INVENTION

In the above-mentioned process, however, there may arise the following problems.

As a first problem, although it becomes easy to fill a space between an adherend and a semiconductor element, voids (air bubbles) may be generated in a sealing resin during mounting of the semiconductor element at a high temperature, so that protection of the surface of the semiconductor element and connection reliability between the semiconductor element and the adherend become inadequate.

Thus, an object of the present invention is to provide a method for producing a semiconductor device, which is capable of suppressing voids during mounting of a semiconductor element to produce a semiconductor device with high reliability.

As a second problem, in the process of JP-B1-4438973, a semiconductor element and an adherend are electrically connected and a space between the former and the latter is filled in parallel, unlike a procedure with a liquid sealing resin in which after completion of electrical connection between a semiconductor element and an adherend, a space between the former and the latter is filled. As a result, adjustment of conditions for mounting a semiconductor element becomes severe, and in some cases, joining of a semiconductor element and an adherend is not satisfactorily performed, so that connection reliability between the semiconductor element and the adherend becomes inadequate.

Thus, another object of the present invention is to provide a method for producing a semiconductor device, which is capable of satisfactorily performing electrical connection between a semiconductor element and an adherend during mounting of the semiconductor element to produce a semiconductor device having high connection reliability.

As a result of conducting vigorous studies on the first problem, the inventors of the present application have arrived at the following findings. A sheet-like sealing resin undergoes a dicing step before mounting of a semiconductor element. In the dicing step, water may be used for heat dissipation and cleaning at the time of dicing. It has been found that water and moisture in the air at the time of dicing are absorbed into the sheet-like sealing resin, and absorbed moisture is evaporated/expanded by heating during mounting, resulting in generation of voids. Based on the findings, the inventors of the present application have found that the objects described above can be achieved by employing the configuration described below, thus leading to completion of the present invention.

That is, the present invention is a method for producing a semiconductor device having an adherend, a semiconductor element electrically connected to the adherend, and an under-fill material for filling a space between the adherend and the semiconductor element, in which the method includes the steps of: providing a sealing sheet having a base material and an under-fill material laminated on the base material; bonding the sealing sheet to a surface of a semiconductor wafer on which a connection member is formed; dicing the semiconductor wafer to form a semiconductor element with the under-fill material; retaining the semiconductor element with the under-fill material at 100 to 200° C. for 1 second or more; and electrically connecting the semiconductor element and the adherend through the connection member while filling a space between the adherend and the semiconductor element using the under-fill material.

According to the production method, since a step of retaining a semiconductor element with an under-fill material at 100 to 200° C. for 1 second or more is provided before the semiconductor element and an adherend are connected, moisture in the under-fill material can be reduced or removed, and resultantly generation of voids during mounting of the semiconductor element can be suppressed to produce a high-reliability semiconductor device.

In the production method, the minimum melt viscosity of the under-fill material at 100 to 200° C. before heat curing is preferably 100 Pa·s or more and 20000 Pa·s or less. Consequently, penetration of the connection member into the under-fill material can be facilitated. In addition, generation of voids at the time of electrical connection of the semiconductor element, and protrusion of the under-fill material from a space between the semiconductor element and the adherend can be prevented. Measurement of the minimum melt viscosity is based on the procedure described in Examples.

In the production method, the viscosity of the under-fill material at 23° C. before heat curing is preferably 0.01 MPa·s or more and 100 MPa·s or less. The under-fill material before heat curing has the above-mentioned viscosity, whereby the retention property of a semiconductor wafer at the time of dicing and the handling property at the time of operation can be improved.

In the production method, the water absorption rate of the under-fill material at a temperature of 23° C. and a humidity of 70% before heat curing is preferably 1% by weight or less. The under-fill material has the above-mentioned water absorption rate, whereby absorption of moisture into the under-fill material is suppressed, so that generation of voids during mounting of the semiconductor element can be more efficiently suppressed.

As a result of conducting vigorous studies on the second problem, the inventors of the present application have found that the objects described above can be achieved by employing the configuration described below, thus leading to completion of the present invention.

That is, the present invention is a method for producing a semiconductor device having an adherend, a semiconductor element electrically connected to the adherend, and an under-fill material for filling a space between the adherend and the semiconductor element, wherein the method includes:

a providing step of providing a sealing sheet having a base material and an under-fill material laminated on the base material;

a bonding step of bonding together a surface of a semiconductor wafer, on which a connection member is formed, and the sealing sheet; a dicing step of dicing the semiconductor wafer to form a semiconductor element with the under-fill material; and

a connection step of electrically connecting the semiconductor element and the adherend through the connection member while filling a space between the adherend and the semiconductor element using the under-fill material, and

the connection step includes the steps of:

contacting the connection member and the adherend with each other under a temperature α of the following requirement (1); and

fixing the contacted connection member to the adherend under a temperature β of the following requirement (2).

Requirement (1): melting point of connection member−100° C.≦α<melting point of connection member

Requirement (2): melting point of connection member≦β≦melting point of connection member+100° C.

According to the production method, first the connection member of the semiconductor element and the adherend are contacted with each other under heating at a predetermined temperature α, which is lower than the melting point of the connection member, at the time of electrically connecting the semiconductor element and the adherend. Consequently, the under-fill material is softened, so that penetration of the connection member into the under-fill material can be facilitated, and contact of the connection member and the adherend can be kept at an adequate level. In this state, the connection member and the adherend are fixed to each other at a predetermined temperature β, which is equal to or higher than the melting point of the connection member, to obtain electrical connection, and therefore a semiconductor device having high connection reliability can be efficiently produced.

In the production method, the minimum melt viscosity of the under-fill material at a range of the temperature a of the requirement (1) before heat curing is preferably 100 Pa·s or more and 20000 Pa·s or less. Consequently, penetration of the connection member into the under-fill material can be facilitated. In addition, generation of voids at the time of electrical connection of the semiconductor element, and protrusion of the under-fill material from a space between the semiconductor element and the adherend can be prevented. Measurement of the minimum melt viscosity is based on the procedure described in Examples.

In the production method, the viscosity of the under-fill material at 23° C. before heat curing is preferably 0.01 MPa·s or more and 100 MPa·s or less. The under-fill material before heat curing has the above-mentioned viscosity, whereby the retention property of a semiconductor wafer at the time of dicing and the handling property at the time of operation can be improved.

In the production method, the water absorption rate of the under-fill material at a temperature of 23° C. and a humidity of 70% before heat curing is preferably 1% by weight or less. The under-fill material has the above-mentioned water absorption rate, whereby absorption of moisture into the under-fill material is suppressed, so that generation of voids during mounting of the semiconductor element can be efficiently suppressed.

In the production method, it is preferable that the height X (μm) of the connection member of the semiconductor wafer and the thickness Y (μm) of the under-fill material satisfy the following relationship.

0.5≦Y/X≦2

The height X (μm) of the connection member and the thickness Y (μm) of the under-fill material satisfy the above relationship, whereby a space between the semiconductor element and the adherend can be sufficiently filled, and excessive protrusion of the under-fill material from the space can be prevented, so that contamination of the semiconductor element by the under-fill material, and so on can be prevented. Even when the absolute value of the height X of the connection member is larger than the absolute value of the thickness Y of the under-fill material, the height X of the connection member decreases as the connection member is melted at the time of mounting as long as the above relationship is satisfied, so that electrical connection between the semiconductor element and the adherend can be satisfactorily performed.

### BRIEF DESCRIPTION OF THE DRAWINGS

FIG. 1 is a sectional schematic view showing a sealing sheet according to one embodiment of the present invention;

FIG. 2A is a sectional schematic view showing a step for producing a semiconductor device according to one embodiment of the present invention;

FIG. 2B is a sectional schematic view showing a step for producing a semiconductor device according to one embodiment of the present invention;

FIG. 2C is a sectional schematic view showing a step for producing a semiconductor device according to one embodiment of the present invention;

FIG. 2D is a sectional schematic view showing a step for producing a semiconductor device according to one embodiment of the present invention; and

FIG. 3 is a sectional schematic view showing a sealing sheet according to another embodiment of the present invention.

### DETAILED DESCRIPTION OF THE PREFERRED EMBODIMENTS

### First Embodiment

The present invention is a method for producing a semiconductor device having an adherend, a semiconductor element electrically connected to the adherend, and an under-fill material for filling a space between the adherend and the semiconductor element, in which the method includes the steps of: providing a sealing sheet having a base material and an under-fill material laminated on the base material; bonding the sealing sheet to a surface of a semiconductor wafer on which a connection member is formed; dicing the semiconductor wafer to form a semiconductor element with the under-fill material; retaining the semiconductor element with the under-fill material at 100 to 200° C. for 1 second or more; and electrically connecting the semiconductor element and the adherend through the connection member while filling a space between the adherend and the semiconductor element using the under-fill material. A first embodiment as one embodiment of the present invention will be described below.

### [Sealing Sheet Providing Step]

In a sealing sheet providing step, a sealing sheet having a base material and an under-fill material laminated on the base material is provided.

### (Sealing Sheet)

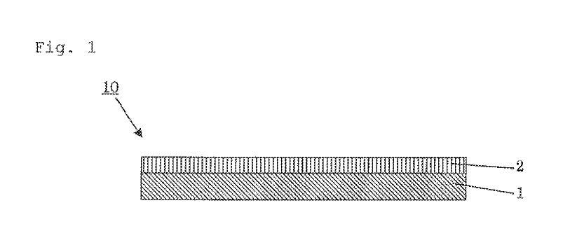

As shown in FIG. 1, a sealing sheet 10 includes a base material 1 and an under-fill material 2 laminated on the base material 1. The under-fill material 2 is not necessarily laminated on the entire surface of the base material 1, but may be provided in a size sufficient for bonding with a semiconductor wafer.

### (Base Material)

The base material 1 is a reinforcement matrix for the sealing sheet 10. Examples of the material for forming the base material 1 include polyolefins such as low-density polyethylene, linear polyethylene, medium-density polyethylene, high-density polyethylene, very low-density polyethylene, random copolymerized polypropylene, block copolymerized polypropylene, homo polypropylene, polybutene and polymethylpentene, an ethylene-vinyl acetate copolymer, an ionomer resin, an ethylene-(meth) acrylic acid copolymer, an ethylene-(meth)acrylate (random, alternating) copolymer, an ethylene-butene copolymer, an ethylene-hexene copolymer, polyurethane, polyesters such as polyethylene terephthalate and polyethylene naphthalate, polycarbonate, polyimide, polyether ether ketone, polyimide, polyetherimide, polyamide, total aromatic polyamide, polyphenyl sulfide, alamid (paper), glass, glass cloth, a fluororesin, polyvinyl chloride, polyvinylidene chloride, a cellulose-based resin, a silicone resin, a metal (foil), and papers such as glassine paper.

In addition, examples of the material of the base material 1 include polymers such as crosslinked products of the resins listed above. For the plastic film described above, an unstretched film may be used, or a film subjected to uniaxial or biaxial stretching may be used as necessary. With a sealing sheet made heat-shrinkable by stretching or the like, collection of semiconductor chips can be facilitated by reducing the bonding area of the base material 1 and the under-fill material 2 by heat-shrinking the base material 1 of the sealing sheet after dicing.

The surface of the base material 1 can be subjected to a common surface treatment, for example, a chemical or physical treatment such as a chromic acid treatment, ozone exposure, flame exposure, high-voltage electrical shock exposure or an ionized radiation treatment, or a coating treatment with a primer (e.g. adhesive substance to be described) for improving adhesion with an adjacent layer, the retention property and so on.

For the base material 1, the same material or different materials can be appropriately selected and used, and one obtained by blending several materials can be used as necessary. The base material 1 can be provided thereon with a vapor-deposited layer of an electrically conductive substance made of a metal, an alloy, an oxide thereof, or the like and having a thickness of about 30 to 500 Å for imparting an antistatic property. The base material 1 may be a single layer or a multiple layer having two or more layers.

The thickness of the base material 1 is not particularly limited, and can be appropriately determined, but is generally about 5 to 200 μm.

### (Under-Fill Material)

An under-fill material 2 in this embodiment can be used as a film for sealing, which fills a space between a surface-mounted semiconductor element and an adherend. Examples of the constituent material of the under-fill material include those obtained by combining a thermoplastic resin and a thermosetting resin. A material made of a thermoplastic resin or a thermosetting resin alone can also be used.

Examples of the thermoplastic resin include natural rubber, butyl rubber, isoprene rubber, chloroprene rubber, an ethylene-vinyl acetate copolymer, an ethylene-acrylic acid copolymer, an ethylene-acrylate copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET and PBT, a polyamideimide resin, and a fluororesin. These thermoplastic resins can be used alone, or in combination of two or more thereof. Among these thermoplastic resins, an acrylic resin, which has less ionic impurities, has a high heat resistance and can ensure the reliability of a semiconductor element, is especially preferable.

The acrylic resin is not particularly limited, and examples thereof include polymers having as a component one or more of esters of acrylic acids or methacrylic acids which have a linear or branched alkyl group having 30 or less of carbon atoms, especially 4 to 18 carbon atoms. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group and an eicosyl group.

Other monomers for forming the polymer are not particularly limited, and examples thereof include carboxyl group-containing monomers such as acrylic acid, methacrylic acid, carboxyethyl acrylate, carboxypentyl acrylate, itaconic acid, maleic acid, fumaric acid and crotonic acid, acid anhydride monomers such as maleic anhydride and itaconic anhydride, hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate and (4-hydroxymethylcyclohexyl)-methyl acrylate, sulfonic acid group-containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate and (meth) acryloyloxynaphthalenesulfonic acid, and phosphoric acid group-containing monomers such as 2-hydroxyethylacryloyl phosphate.

Examples of the thermosetting resin include a phenol resin, an amino resin, an unsaturated polyester resin, an epoxy resin, a polyurethane resin, a silicone resin and a thermosetting polyimide resin. These resins can be used alone, or in combination of two or more thereof. Particularly, an epoxy resin containing less ionic impurities that corrode a semiconductor element is preferable. A curing agent for the epoxy resin is preferably a phenol resin.

The epoxy resin is not particularly limited as long as it is generally used as an adhesive composition, and for example a difunctional epoxy resin or a polyfunctional epoxy resin such as a bisphenol A type, a bisphenol F type, a bisphenol S type, a brominated bisphenol A type, a hydrogenated bisphenol A type, a bisphenol AF type, a biphenyl type, a naphthalene type, a fluorene type, a phenol novolak type, an orthocresol novolak type, a trishydroxyphenyl methane type or a tetraphenylol ethane type, or an epoxy resin such as a hydantoin type, a trisglycidyl isocyanurate type or a glycidyl amine type is used. They can be used alone, or in combination of two or more thereof. Among these epoxy resins, a novolak type epoxy resin, a biphenyl type epoxy resin, a trishydroxyphenyl methane type resin or a tetraphenylol ethane type epoxy resin is especially preferable. This is because the aforementioned resins have a high reactivity with a phenol resin as a curing agent, and are excellent in heat resistance and so on.

Further, the phenol resin acts as a curing agent for the epoxy resin, and examples thereof include novolak type phenol resins such as a phenol novolak resin, a phenol aralkyl resin, a cresol novolak resin, a tert-butylphenol novolak resin, and a nonylphenol novolak resin, resole type phenol resins, and polyoxystyrenes such as polyparaoxystyrene. They can be used alone, or in combination of two or more thereof. Among these phenol resins, a phenol novolak resin and a phenol aralkyl resin are especially preferable. This is because the connection reliability of a semiconductor device can be improved.

For example, the epoxy resin and the phenol resin are preferably blended at such a blending ratio that the equivalent of the hydroxyl group in the phenol resin per one equivalent of the epoxy group in the epoxy resin component is 0.5 to 2.0 equivalents. More preferable is 0.8 to 1.2 equivalents. That is, if the blending ratio of the resins falls out of the aforementioned range, the curing reaction does not proceed sufficiently, so that properties of the epoxy resin cured products are easily deteriorated.

In the present invention, an under-fill material using an epoxy resin, a phenol resin and an acrylic resin is especially preferable. These resins have less ionic impurities and has a high heat resistance, and therefore can ensure the reliability of a semiconductor element. The blending ratio in this case is such that the mixed amount of the epoxy resin and the phenol resin is 10 to 200 parts by weight based on 100 parts by weight of the acrylic resin component.

A heat curing accelerating catalyst for the epoxy resin and the phenol resin is not particularly limited, and can be appropriately selected from known heat curing accelerating catalysts and used. The heat curing accelerating catalyst can be used alone, or in combination or two or more kinds. As the heat curing accelerating catalyst, for example, an amine-based curing accelerator, a phosphorus-based curing accelerator, an imidazole-based curing accelerator, a boron-based curing accelerator or phosphorus-boron-based curing accelerator can be used.

A flux may be added to the under-fill material 2 for removing an oxide film on the surface of a solder bump to facilitate mounting of a semiconductor element. The flux is not particularly limited, a previously known compound having an a flux action can be used, and examples thereof include diphenolic acid, adipic acid, acetylsalicylic acid, benzoic acid, benzilic acid, azelaic acid, benzylbenzoic acid, malonic acid, 2,2-bis(hydroxymethyl)propionic acid, salicylic acid, o-methoxybenzoic acid, m-hydroxybenzoic acid, succinic acid, 2,6-dimethoxymethyl paracresol, hydrazide benzoate, carbohydrazide, dihydrazide malonate, dihydrazide succinate, dihydrazide glutarate, hydrazide salicylate, dihydrazide iminodiacetate, dihydrazide itaconate, trihydrazide citrate, thiocarbohydrazide, benzophenone hydrazone, 4,4′-oxybisbenzenesulfonyl hydrazide and dihydrazide adipate. The added amount of the flux may be such an amount that the flux action is exhibited, and is normally about 0.1 to 20 parts by weight based on 100 parts by weight of the resin component contained in the under-fill material.

In this embodiment, the under-fill material 2 may be colored as necessary. In the under-fill material 2, the color shown by coloring is not particularly limited, but is preferably, for example, black, blue, red and green. For coloring, a colorant can be appropriately selected from known colorants such as pigments and dyes and used.

When the under-fill material 2 of this embodiment is preliminarily crosslinked to a certain degree, a polyfunctional compound that reacts with a functional group or the like at the end of the molecular chain of a polymer should be added as a crosslinker at the time of preparation. Consequently, adhesion properties under a high temperature can be improved to improve the heat resistance.

As the crosslinker, particularly polyisocyanate compounds such as tolylene diisocyanate, diphenylmethane diisocyanate, p-phenylene diisocyanate, 1,5-naphthalene diisocyanate and an adduct of a polyhydric alcohol and a diisocyanate are more preferable. Preferably, the added amount of the crosslinker is normally 0.05 to 7 parts by weight based on 100 parts by weight of the polymer. If the amount of crosslinker is more than 7 parts by weight, the adhering strength is reduced, thus being not preferable. On the other hand, if the amount of the crosslinker is less than 0.05 parts by weight, the cohesive strength becomes poor, thus being not preferable. Other polyfunctional compounds such as an epoxy resin may be included as necessary together with the above-mentioned polyisocyanate compound.

An inorganic filler can be appropriately blended with the under-fill material 2. Blending of the inorganic filler allows impartment of electrical conductivity, improvement of thermal conductivity, adjustment of a storage elastic modulus, and so on.

Examples of the inorganic filler include various inorganic powders made of, for example, ceramics such as silica, clay, plaster, calcium carbonate, barium sulfate, aluminum oxide, beryllium oxide, silicon carbide and silicon nitride, metals such as aluminum, copper, silver, gold, nickel, chromium, lead, tin, zinc, palladium and solder, or alloys, and carbon. They can be used alone, or in combination of two or more thereof. Above all, silica, particularly fused silica is suitably used.

The average particle diameter of the inorganic filler is not particularly limited, but is preferably in a range of 0.005 to 10 μm, more preferably in a range of 0.01 to 5 μm, further preferably in a range of 0.1 to 2.0 μm. If the average particle diameter of the inorganic filler is less than 0.005 μm, the flexibility of the under-fill material may be thereby depressed. On the other hand, if the average particle diameter is more than 10 μm, the particle diameter may be so large with respect to a gap sealed by the under-fill material that the sealing property is depressed. In the present invention, inorganic fillers having mutually different average particle diameters may be combined and used. The average particle diameter is a value determined by a photometric particle size analyzer (manufactured by HORIBA, Ltd.; Unit Name: LA-910).

The blending amount of the inorganic filler is preferably 10 to 400 parts by weight, more preferably 50 to 250 parts by weight, based on 100 parts by weight of the organic resin component. If the blending amount of the inorganic filler is less than 10 parts by weight, the storage elastic modulus may be reduced, thereby considerably deteriorating the stress reliability of a package. On the other hand, if the blending amount of the inorganic filler is more than 400 parts by weight, the fluidity of the under-fill material 2 may be depressed, so that the under-fill material may not sufficiently fill up raised and recessed portions of the substrate or semiconductor element, thus leading to generation of voids and cracks.

Besides the inorganic filler, other additives can be blended with the under-fill material 2 as necessary. Examples of other additives include a flame retardant, a silane coupling agent and an ion trapping agent. Examples of the flame retardant include antimony trioxide, antimony pentaoxide and a brominated epoxy resin. They can be used alone, or in combination of two or more thereof. Examples of the silane coupling agent include β-(3,4-epoxycyclohexyl)ethyltrimethoxysilane, γ-glycidoxypropyltrimethoxysilane and γ-glycidoxypropylmethyldiethoxysilane. These compounds can be used alone, or in combination of two or more thereof. Examples of the ion trapping agent include a hydrotalcite and bismuth hydroxide. They can be used alone, or in combination of two or more thereof.

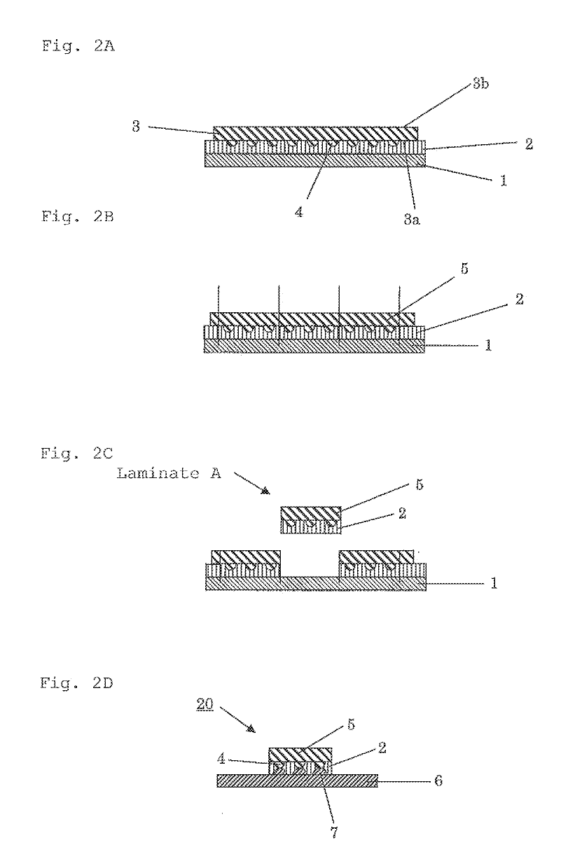

In this embodiment, the minimum melt viscosity of the under-fill material 2 at 100 to 200° C. before heat curing is preferably 100 Pa·s or more and 20000 Pa·s or less, more preferably 1000 Pa·s or more and 10000 Pa·s or less. By ensuring that the minimum melt viscosity is in the above-mentioned range, penetration of a connection member 4 into the under-fill material 2 (see FIG. 2A) can be facilitated. In addition, generation of voids at the time of electrical connection of a semiconductor element 5, and protrusion of the under-fill material 2 from a space between the semiconductor element 5 and an adherend 6 can be prevented (see FIG. 2D).

The viscosity of the under-fill material 2 at 23° C. before heat curing is preferably 0.01 MPa·s or more and 100 MPa·s or less, more preferably 0.1 MPa·s or more and 10 MPa·s or less. The under-fill material before heat curing has a viscosity in the above-mentioned range, whereby the retention property of a semiconductor wafer 3 (see FIG. 2B) at the time of dicing and the handling property at the time of operation can be improved.

Further, the water absorption rate of the under-fill material 2 at a temperature of 23° C. and a humidity of 70% before heat curing is preferably 1% by weight or less, more preferably 0.5% by weight or less. The under-fill material 2 has such a water absorption rate as described above, whereby absorption of moisture into the under-fill material 2 can be suppressed, so that generation of voids during mounting of the semiconductor element 5 can be more efficiently suppressed. The lower limit of the water absorption rate is preferably as low as possible, and is preferably substantially 0% by weight, more preferably 0% by weight.

The thickness of the under-fill material 2 (total thickness in the case of a multiple layer) is not particularly limited, but may be about 10 μm to 100 μm when considering the strength of the under-fill material 2 and performance of filling a space between the semiconductor element 5 and the adherend 6. The thickness of the under-fill material 2 may be appropriately set inconsideration of the gap between the semiconductor element 5 and the adherend 6 and the height of the connection member.

The under-fill material 2 of the sealing sheet 10 is preferably protected by a separator (not shown). The separator has a function as a protective material for protecting the under-fill material 2 until practical use. The separator is peeled off when the semiconductor wafer 3 is attached onto the under-fill material of the sealing sheet. As the separator, polyethylene terephthalate (PET), polyethylene, polypropylene, or a plastic film or paper of which surface is coated with a release agent such as a fluorine-based release agent or a long-chain alkyl acrylate-based release agent can be used.

### (Method for Producing a Sealing Sheet)

A method for producing a sealing sheet according to this embodiment includes a step of forming the under-fill material 2 on the base material 1.

Examples of the method for a film formation of the base material 1 may include a calender film formation method, a casting method in an organic solvent, an inflation extrusion method in a closed system, a T-die extrusion method, a co-extrusion method and a dry lamination method. For the material of the base material 1, the material described above may be used.

When the base material is used as a release film, the method for preparation thereof is not particularly limited and for example, a release film can be made by forming a release coat layer such as a silicone layer on a surface of the base material to which the under-fill material is bonded.

As a step of forming the under-fill material 3, mention is made of, for example, a method of carrying out a step of forming a coating layer by applying an adhesive composition solution as a constituent material of the under-fill material onto a release film as the base material 1, and thereafter carrying out a step of drying the coating layer.

The method for applying the adhesive composition solution is not limited, and examples thereof include methods of applying the solution using a comma coating method, a fountain method, a gravure method and the like. The coating thickness may be appropriately set so that the thickness of the under-fill material which is finally obtained by drying the coating layer falls within the range described above. Further, the viscosity of the adhesive composition solution is not particularly limited, and is preferably 400 to 2500 mPa·s, more preferably 800 to 2000 mPa·s at 25° C.

Drying the coating layer may be carried out in a general heating furnace, and at this time, dry air may be blown to the coating layer.

The drying time is appropriately set according to the coating thickness of the adhesive composition solution, and is in a range of normally 1 to 5 min, more preferably 2 to 4 min. If the drying time is less than 1 min, there may be a case where the amount of a remaining solvent increases, or the curing reaction does not sufficiently proceed, so that the amount of unreacted curable component and remaining solvent increases, thus raising problems of outgassing and voids in subsequent steps. On the other hand, if the drying time is more than 5 min, the fluidity and performance of filling up a bump of the semiconductor wafer may be depressed as a result of too advanced curing reaction.

The drying temperature is not particularly limited, and is normally set to a temperature in a range of 70 to 160° C. However, in the present invention, it is preferable to elevate the drying temperature stepwise with the elapse of drying time. Specifically, for example, the drying temperature is set to a temperature in a range of 70° C. to 100° C. in an initial stage of drying (for 1 min or less just after the start of drying), and is set to a temperature in a range of 100 to 160° C. in a late stage of drying (from more than 1 min to 5 min or less). Consequently, generation of pinholes on the surface of the coating layer, which are generated when the drying temperature is rapidly elevated just after coating, can be prevented.

The release film may be bonded to the other surface of the under-fill material, used as a protective film for the sealing sheet, and peeled off at the time of bonding to the semiconductor wafer or the like. Consequently, the sealing sheet according to this embodiment having the under-fill material can be produced.

### [Bonding Step]

In a bonding step, a surface of the semiconductor wafer, on which the connection member is formed, and the sealing sheet are bonded together (see FIG. 2A).

### (Semiconductor Wafer)

As the semiconductor wafer 3, a plurality of connection members 4 may be formed on one surface 3a (see FIG. 2A), or connection members may be formed on both surfaces 3a and 3b of the semiconductor wafer 3 (not shown). The material of the connection member such as a bump or an electrically conductive material is not particularly limited, and examples thereof include solders (alloys) such as a tin-lead-based metal material, a tin-silver-based metal material, a tin-silver-copper-based metal material, a tin-zinc-based metal material, a tin-zinc-bismuth-based metal material, a gold-based metal material and a copper-based metal material. The height of the connection member is also determined according to an application, and is generally about 15 to 100 μm. Of course, the heights of individual connection members in the semiconductor wafer 3 may be the same or different.

When the connection members are formed on both surfaces of the semiconductor wafer, the connection members may or may not be electrically connected. Examples of electrical connection between connection members include connection through a via, which is called a TSV type.

In the method for producing a semiconductor device according to this embodiment, as the thickness of the under-fill material, the height X (μm) of the connection member formed on the surface of the semiconductor wafer and the thickness Y (μm) of the under-fill material preferably satisfies the following relationship:

0.5≦Y/X≦2

The height X (μm) of the connection member and the thickness Y (μm) of the cured film satisfy the above relationship, whereby a space between the semiconductor element and the adherend can be sufficiently filled, and excessive protrusion of the under-fill material from the space can be prevented, so that contamination of the semiconductor element by the under-fill material, and so on can be prevented. When the heights of the respective connection members are different, the height of the highest connection member is used as the reference.

### (Bonding)

As shown in FIG. 2A, first a separator that is optionally provided on the under-fill 2 of the sealing sheet 10 is appropriately peeled off, the surface (connection member forming surface) 3a of the semiconductor wafer 3, on which the connection member 4 is formed, and the under-fill material 2 are made to face to each other, and the under-fill material 2 and the semiconductor wafer 3 are bonded together (mount step).

The method for bonding is not particularly limited, but is preferably a method by pressure-bonding. Pressure-bonding is normally performed by pressing with a pressure of preferably 0.1 to 1 MPa, more preferably 0.3 to 0.7 MPa by known pressing means such as a pressure roller. At this time, pressure-bonding may be carried out while heating to about 40 to 100° C. It is also preferable to carry out pressure-bonding under a reduced pressure (1 to 1000 Pa) for improving adhesion.

### [Dicing Step]

In a dicing step, as shown in FIG. 2B, a semiconductor wafer is diced to form a semiconductor element with an under-fill material. Through the dicing step, the semiconductor wafer 3 is cut to a predetermined size and thereby formed into individual pieces (small pieces) to produce a semiconductor chip (semiconductor element) 5. The semiconductor chip 5 thus obtained is integrated with the under-fill material 2 cut in the same shape. Dicing is carried out from the surface 3b opposite to the surface 3a of the semiconductor wafer 3, to which the under-fill material 2 is bonded, in accordance with a usual method. Alignment of cut areas can be performed by image recognition using direct light or indirect light or infrared rays (IR).

In this step, for example, a cutting method called full cut, in which cutting is made to a sealing sheet, can be employed. The dicing device used in this step is not particularly limited, and one that is previously known can be used. The semiconductor wafer is adhesively fixed with excellent adhesion by a sealing sheet having an under-fill material, so that chipping and chip fly can be suppressed, and also damage of the semiconductor wafer can be suppressed. When the under-fill material is formed from a resin composition containing an epoxy resin, occurrence of glue protrusion of the under-fill material at the cut surface can be suppressed or prevented even though the under-fill material is cut by dicing. As a result, reattachment of cut surfaces (blocking) can be suppressed or prevented, so that pickup described later can be further satisfactorily performed.

When expanding of the sealing sheet is carried out subsequently to the dicing step, the expanding can be carried out using a previously known expanding device. The expanding device has a doughnut-like outer ring capable of pushing down the sealing sheet via a dicing ring, and an inner ring having a diameter smaller than that of the outer ring and supporting the sealing sheet. Owing to the expanding step, adjacent semiconductor chips can be prevented from contacting with each other and being damaged in a pickup step described later.

### [Pickup Step]

As shown in FIG. 2C, pickup of the semiconductor chip 5 with the under-fill material 2 is carried out to peel off a laminate A of the semiconductor chip 5 and the under-fill material 3 from the base material 1 for collecting the semiconductor chip 5 adhesively fixed on the sealing sheet.

The method for pickup is not particularly limited, and previously known various methods can be employed. Mention is made of, for example, a method in which individual semiconductor chips are pushed up by a needle from the base material side of the sealing sheet, and the semiconductor chips, which have been pushed up, are collected by a pickup device. The semiconductor chip 5, which has been picked up, is integrated with the under-fill material 2 bonded to the surface 3a to form the laminate A.

### [Retention Step]

In a retention step, the semiconductor element 5 with the under-fill material 2 (laminate A) is retained at 100 to 200° C. for second or more. Consequently, moisture in the under-fill material can be reduced or removed, and resultantly generation of voids during mounting of the semiconductor element can be suppressed to produce a high-reliability semiconductor device.

The retention temperature is not particularly limited as long as it is in a range of 100 to 200° C., and a selection can be appropriately made in consideration of the amount of moisture in the under-fill material 2 and a moisture dissipation property. Further, in light of production efficiency, the retention temperature is preferably 120 to 180° C., more preferably 140 to 160° C.

The retention time is not particularly limited as long as it is not less than 1 second, and like the retention temperature, a selection can be appropriately made in consideration of the amount of moisture in the under-fill material 2 and a moisture dissipation property. In light of production efficiency, the retention time is preferably 1 second to 60 minutes, more preferably 1 second to 2 minutes, further preferably 1 second to 1 minute.

This retention step may be carried out in the pickup device during the transition from the pickup step to a mounting process while changing the setting of the pickup device, or may be carried out such that the laminate A is made to stay in a heating furnace for a predetermiend time separately.

### [Connection Step]

In a connection step, the semiconductor element and the adherend are electrically connected through the connection member while filling a space between the adherend and the semiconductor element using the under-fill material (so called a mounting process; see FIG. 2D). Specifically, the semiconductor chip 5 of the laminate A is fixed to the adherend 6 in accordance with a usual method in such a form that the connection member forming surface 3a of the semiconductor chip 5 faces to the adherend 6. For example, the bump (connection member) 4 formed on the semiconductor chip 5 is contacted with an electrically conductive material 7 (solder or the like) for bonding, which is attached to the connection pad of the adherend 6, and the electrically conductive material is melted while pressing, whereby electrical connection between the semiconductor chip 5 and the adherend 6 can be provided to fix the semiconductor chip 5 to the adherend 6. Since the under-fill material 2 is bonded to the connection member forming surface 3a of the semiconductor chip 5, a space between the semiconductor chip 5 and the adherend 6 is filled with the under-fill material 2 concurrently with electrically connecting of the semiconductor chip 5 and the adherend 6.

Generally, in the mounting process, the temperature is 100 to 300° C. as a heating condition, and the pressure is 0.5 to 500 N as a pressing condition. A heat pressure-bonding treatment in the mounting process may be carried out in a multiple stage. For example, such a procedure can be employed that a treatment is carried out at 150° C. and 100 N for 10 seconds, followed by carrying out a treatment at 300° C. and 100 to 200 N for 10 seconds. By carrying out the heat pressure-bonding treatment in a multiple stage, a resin between the connection member and the pad can be efficiently removed to obtain a better metal-metal joint.

As the adherend 6, a lead frame, various kinds of substrates such as a circuit substrate (such as a wiring circuit substrate), and other semiconductor elements can be used. Examples of the material of the substrate include, but are not limited to, a ceramic substrate and a plastic substrate. Examples of the plastic substrate include an epoxy substrate, a bismaleimide triazine substrate, a polyimide substrate and a glass epoxy substrate.

In the connection step, one or both of the connection member and the electrically conductive material are melted to connect the bump 4 of the connection member forming surface 3a of the semiconductor chip 5, and the electrically conductive material 7 on the surface of the adherend 6, and the temperature at which the bump 4 and the electrically conductive material 7 are melted is normally about 260° C. (for example 250° C. to 300° C.). The sealing sheet according to this embodiment can be made to have a such a heat resistance that it can endure a high temperature in the mounting process, by forming the under-fill material 2 from an epoxy resin or the like. Measurement of the melting point of the bump can be performed by measuring 10 mg of a metal having the same composition as that of the bump in a process of heating at 5° C./min using a DSC (differential scanning calorimeter).

### [Under-Fill Material Curing Step]

After performing electrical connection between the semiconductor element 5 and the adherend 6, the under-fill material is cured by heating. Consequently, the surface of the semiconductor element 5 can be protected, and connection reliability between the semiconductor element 5 and the adherend 6 can be ensured. The heating temperature for curing the under-fill material is not particularly limited, and may be about 150 to 250° C.

### [Sealing Step]

Next, a sealing step may be carried out for protecting the whole of a semiconductor device 20 including the mounted semiconductor chip 5. The sealing step is carried out using a sealing resin. The sealing conditions at this time are not particularly limited, and normally the sealing resin is heat-cured by heating at 175° C. for 60 seconds to 90 seconds, but the present invention is not limited thereto and, for example, the sealing resin may be cured at 165° C. to 185° C. for several minutes.

The sealing resin is not particularly limited as long as it is a resin having an insulating property (insulating resin), and can be selected from sealing materials such as known sealing resins and used, but an insulating resin having elasticity is more preferable. Examples of the sealing resin include a resin composition containing an epoxy resin. Examples of the epoxy resin include the epoxy resins described previously as an example. The sealing resin by the resin composition containing an epoxy resin may contain, as a resin component, a thermosetting resin (phenol resin, etc.), a thermoplastic resin and so on in addition to an epoxy resin. The phenol resin can also be used as a curing agent for the epoxy resin, and examples of such a phenol resin include the phenol resins described previously as an example.

### [Semiconductor Device]

A semiconductor device obtained using the sealing sheet will now be described with reference to the drawings (see FIG. 2D). In the semiconductor device 20 according to this embodiment, the semiconductor element 5 and the adherend 6 are electrically connected through the bump (connection member) 4 formed on the semiconductor element 5 and the electrically conductive material 7 provided on the adherend 6. The under-fill material 2 is placed between the semiconductor element 5 and the adherend 6 so as to fill a space therebetween. The semiconductor device 20 is obtained by the above-mentioned production method using the sealing sheet 10, and therefore generation of voids during mounting of the semiconductor element 5 is suppressed. Thus, protection of the surface of the semiconductor element 5 and filling of a space between the semiconductor element 5 and the adherend 6 are kept at an adequate level, so that high reliability can be exhibited as the semiconductor device 20.

### Second Embodiment

The present invention is a method for producing a semiconductor device having an adherend, a semiconductor element electrically connected to the adherend, and an under-fill material for filling a space between the adherend and the semiconductor element, in which the method includes: a providing step of providing a sealing sheet having a base material and an under-fill material laminated on the base material; a bonding step of bonding together a surface of a semiconductor wafer, on which a connection member is formed, and the sealing sheet; a dicing step of dicing the semiconductor wafer to form a semiconductor element with the under-fill material; and a connection step of electrically connecting the semiconductor element and the adherend through the connection member while filling a space between the adherend and the semiconductor element using the under-fill material, and the connection step includes the steps of: contacting the connection member and the adherend with each other under a temperature a of the following requirement (1); and fixing the contacted connection member to the adherend under a temperature β of the following requirement (2).

Requirement (1): melting point of connection member−100° C.≦α<melting point of connection member

Requirement (2): melting point of connection member≦β≦melting point of connection member+100° C.

A second embodiment as one embodiment of the present invention will be described below with reference to the drawings as necessary. For the second embodiment, the same steps as in the first embodiment can be employed except that the retention step of the first embodiment is not included, and the connection step is changed to a connection step specific to this embodiment. Thus, exemplary steps of this embodiment include a sealing sheet providing step, a bonding step, a dicing step, a pickup step and a connection step, and include an under-fill material curing step and a sealing step as necessary. Aspects different from the first embodiment will be described below.

### [Connection Step]

The connection step of this embodiment includes a step of contacting the connection member and the adherend with each other under a temperature α of the following requirement (1) (hereinafter, referred to as a “contact step” in some cases), and a step of fixing the contacted connection member to the adherend under a temperature of β of the following requirement (2) (hereinafter, referred to as a “fixation step” in some cases).

Requirement (1): melting point of connection member−100° C.≦α<melting point of connection member

Requirement (2): melting point of connection member≦β≦melting point of connection member+100° C.

According to this embodiment, first in the contact step, the connection member of the semiconductor element and the adherend are contacted with each other under heating at a predetermined temperature α, which is lower than the melting point of the connection member, at the time of electrically connecting the semiconductor element and the adherend. Consequently, the under-fill material is softened, so that penetration of the connection member into the under-fill material can be facilitated, and contact of the connection member and the adherend can be kept at an adequate level. Next, in the fixation step, the connection member and the adherend are fixed to each other at a predetermined temperature β, which is equal to or higher than the melting point of the connection member, to obtain electrical connection while maintaining the contact state, and therefore a semiconductor device having high connection reliability can be efficiently produced.

In this embodiment, the requirement (1) in the contact step and the requirement (2) in the fixation step are the above-mentioned ranges, but are preferably the following ranges (1′) and (2′), respectively, from the viewpoint of ease of softning of the under-fill material, and prevention of an unintended heat history in the connection member.

Requirement (1′): melting point of connection member−80° C.≦α≦a melting point of connection member−10° C.

Requirement (2′): melting point of connection member+10° C.≦β<melting point of connection member+80° C.

Time periods for retaining the requirement (1) in the contact step and the requirement (2) in the fixation step are not particularly limited as long as contact of the connection member of the semiconductor element and the adherend and fixation of the semiconductor element to the adherend through the connection member can be achieved, and are, each independently, preferably 2 to 20 seconds, more preferably 3 to 15 seconds. For improving the reliability of processes in the contact step and the fixation step, the steps may be carried out under pressure. For the pressing condition, the pressure is preferably 10 to 200 N, more preferably 20 to 160 N independently for each step.

In this embodiment, the minimum melt viscosity of the under-fill material 2 at a range of the temperature a of the requirement (1) before heat curing is preferably 100 Pa·s or more and 20000 Pa·sor less, more preferably 1000 Pa·s or more and 10000 Pa·s or less. By ensuring that the minimum melt viscosity is in the above-mentioned range, penetration of a connection member 4 into the under-fill material 2 (see FIG. 2A) can be facilitated. In addition, generation of voids at the time of electrical connection of a semiconductor element 5, and protrusion of the under-fill material 2 from a space between the semiconductor element 5 and an adherend 6 can be prevented (see FIG. 2D).

### Third Embodiment

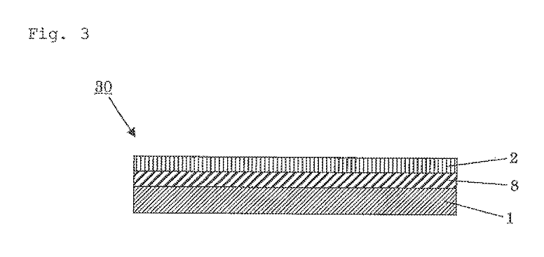

In the first embodiment, a sealing sheet with an under-fill material laminated directly on a base material is described, but the third embodiment describes a sealing sheet provided with a pressure-sensitive adhesive layer between a base material and an under-fill material. FIG. 3 is a sectional schematic view showing a sealing sheet according to the third embodiment that is another embodiment of the present invention.

As shown in FIG. 3, the sealing sheet according to the third embodiment includes a base material 1, a pressure-sensitive adhesive layer 8 laminated on the base material 1, and an under-fill material 2 laminated on the pressure-sensitive adhesive layer 8. Since the base material 1 and the under-fill material 2 are same as those of the first embodiment, the pressure-sensitive adhesive layer 8 is described here.

### (Pressure-Sensitive Adhesive Layer)

The pressure-sensitive adhesive layer 8 may be formed by a previously known pressure-sensitive adhesive, or may be formed by an ultraviolet-ray curing-type pressure-sensitive adhesive. The ultraviolet-ray curing-type pressure-sensitive adhesive is preferable in that the degree of crosslinking can be increased by irradiation of ultraviolet rays to reduce adhesive strength to an under-fill material 2, and a semiconductor element with an under-fill material can be easily picked up.

For the ultraviolet-ray curing-type pressure-sensitive adhesive, one having a ultraviolet ray-curable functional group such as a carbon-carbon double bond and showing adherability can be used without particular limitation. Examples of the ultraviolet-ray curing-type pressure-sensitive adhesive include addition-type ultraviolet-ray curing-type pressure-sensitive adhesives in which an ultraviolet ray-curable monomer component or an oligomer component is blended into general pressure-sensitive adhesives such as an acryl-based pressure-sensitive adhesive and a rubber-based pressure-sensitive adhesive.

As the pressure-sensitive adhesive, an acryl-based pressure-sensitive adhesive having an acryl-based polymer as a base polymer is preferable from the viewpoint of ease of cleaning that an electronic component sensitive to contamination, such as a semiconductor wafer or glass, can be cleaned with ultrapure water or an organic solvent such as an alcohol.

Examples of the acryl-based polymer include acryl-based polymers using as a monomer component one or more of (meth) acrylic acid alkyl esters (for example, linear or branched alkyl esters with the alkyl group having 1 to 30, particularly 4 to 18 carbon atoms, such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nony ester, decyl ester, isodecyl ester, undecyl ester, dodecyl ester, tridecyl ester, tetradecyl ester, hexadecyl ester, octadecyl ester and eicosyl ester) and (meth)acrylic acid cycloalkyl esters (for example, cyclopentyl ester and cyclohexyl ester, etc.). The (meth)acrylic acid ester refers to an acrylic acid ester and/or a methacrylic acid ester, and (meth) has the same meaning throughout the present invention.

The acryl-based polymer may contain a unit corresponding to any other monomer component capable of being copolymerized with the (meth) acrylic acid alkyl ester or cycloalkyl ester as necessary for the purpose of modifying cohesive strength, heat resistance and so on. Examples of the monomer component include carboxyl group-containing monomers such as acrylic acid, methacrylic acid, carboxyethyl (meth)acrylate, carboxypentyl (meth)acrylate, itaconic acid, maleic acid, fumaric acid and crotonic acid; acid anhydride monomers such as maleic anhydride and itaconic anhydride; hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate and (4-hydroxymethylcyclohexyl)-methyl (meth)acrylate; sulfonic acid group-containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate and (meth)acryloyloxynaphthalenesulfonic acid; phosphoric acid group-containing monomers such as 2-hydroxyethylacryloyl phosphate; and acrylamide and acrylonitrile. One or more of these monomers capable of being copolymerized can be used. The used amount of the monomer component capable of copolymerization is preferably 40% by weight or less based on total monomer components.

Further, the acryl-based polymer may contain a polyfunctional monomer or the like as a monomer component for copolymerization as necessary for the purpose of crosslinking. Examples of the polyfunctional monomer include hexanediol di(meth)acrylate, (poly)ethylene glycol di(meth)acrylate, (poly) propylene glycol di(meth)acrylate, neopentylglycol di(meth)acrylate, pentaerythrithol di(meth)acrylate, trimethylolpropane tri(meth)acrylate, pentaerythrithol tri(meth)acrylate, dipentaerythrithol hexa(meth)acrylate, epoxy (meth)acrylate, polyester (meth)acrylate and urethane (meth)acrylate. One or more of these polyfunctional monomers can be used. The used amount of the polyfunctional monomer is preferably 30% by weight or less based on total monomer components from the viewpoint of an adhesion property.

The acryl-based polymer is obtained by subjecting a single monomer or monomer mixture of two or more kinds of monomers to polymerization. Polymerization can be carried out by any method such as solution polymerization, emulsion polymerization, bulk polymerization or suspension polymerization. The content of low-molecular weight substances is preferably low from the viewpoint of prevention of contamination of a clean adherend. In this respect, the number average molecular weight of the acryl-based polymer is preferably 300,000 or more, further preferably about 400,000 to 3,000,000.

For the pressure-sensitive adhesive, an external crosslinker can also be appropriately employed for increasing the number average molecular weight of an acryl-based polymer or the like as a base polymer. Specific examples of the external crosslinking methods include a method in which so called a crosslinker such as a polyisocyanate compound, an epoxy compound, an aziridine compound or a melamine-based crosslinker is added and reacted. When an external crosslinker is used, the used amount thereof is appropriately determined according to a balance with a base polymer to be crosslinked, and further a use application as a pressure-sensitive adhesive. Generally, the external crosslinker is blended in an amount of preferably about 5 parts by weight or less, further preferably 0.1 to 5 parts by weight, based on 100 parts by weight of the base polymer. Further, for the pressure-sensitive adhesive, previously known various kinds of additives, such as a tackifier and an anti-aging agent, may be used as necessary in addition to the aforementioned components.

Examples of the ultraviolet-ray curable monomer component to be blended include urethane oligomer, urethane (meth)acrylate, trimethylolpropane tri(meth)acrylate, tetramethylolmethane tetra(meth)acrylate, pentaerythrithol tri(meth)acrylate, pentaerythrithol tetra(meth)acrylate, dipentaerythrithol monohydroxypenta(meth)acrylate, dipentaerythrithol hexa(meth)acrylate and 1,4-butanediol di(meth)acrylate. Examples of the ultraviolet-ray curable oligomer component include various oligomers such as urethane-based, polyether-based, polyester-based, polycarbonate-based and polybutadiene-based oligomers, and the appropriate molecular weight thereof is in a range of about 100 to 30000. For the blending amount of the ultraviolet-ray curable monomer component or oligomer component, an amount allowing the adhesive strength of the pressure-sensitive adhesive layer to be reduced can be appropriately determined according to the type of the pressure-sensitive adhesive layer. Generally, the blending amount is, for example, 5 to 500 parts by weight, preferably about 40 to 150 parts by weight, based on 100 parts by weight of a base polymer such as an acryl-based polymer forming the pressure-sensitive adhesive.

Examples of the ultraviolet-ray curing-type pressure-sensitive adhesive include, besides the addition-type ultraviolet-ray curing-type pressure-sensitive adhesive described previously, an intrinsic ultraviolet-ray curing-type pressure-sensitive adhesive using, as a base polymer, a polymer having a carbon-carbon double bond in the polymer side chain or main chain or at the end of the main chain. The intrinsic ultraviolet-ray curing-type pressure-sensitive adhesive is preferable because it is not required to contain, or mostly does not contain an oligomer component or the like which is a low-molecular component, and therefore the oligomer component or the like does not migrate in the pressure-sensitive adhesive over time, so that a pressure-sensitive adhesive layer having a stable layer structure can be formed.

For the base polymer having a carbon-carbon double bond, one having a carbon-carbon double bond and also an adherability can be used without no particular limitation. Such a base polymer is preferably one having an acryl-based polymer as a basic backbone. Examples of the basic backbone of the acryl-based polymer include the acryl-based polymers described previously as an example.

The method for introducing a carbon-carbon double bond into the acryl-based polymer is not particularly limited, and various methods can be employed, but it is easy in molecular design to introduce the carbon-carbon double bond into a polymer side chain. Mention is made to, for example, a method in which a monomer having a functional group is copolymerized into an acryl-based polymer beforehand, and thereafter a compound having a functional group that can react with the above-mentioned functional group, and a carbon-carbon double bond is subjected to a condensation or addition reaction while maintaining the ultraviolet-ray curability of the carbon-carbon double bond.

Examples of the combination of these functional groups include a combination of a carboxylic acid group and an epoxy group, a combination of a carboxylic acid group and an aziridyl group and a combination of a hydroxyl group and an isocyanate group. Among these combinations of functional groups, the combination of a hydroxyl group and an isocyanate group is suitable in terms of ease of reaction tracing. The functional group may be present at the side of any of the acryl-based polymer and the aforementioned compound as long as the combination of the functional groups is such a combination that the acryl-based polymer having a carbon-carbon double bond is generated, but for the preferable combination, it is preferred that the acryl-based polymer have a hydroxyl group and the aforementioned compound have an isocyanate group. In this case, examples of the isocyanate compound having a carbon-carbon double bond include metacryloyl isocyanate, 2-metacryloyloxyethyl isocyanate, m-isopropenyl-α,α-dimethylbenzyl isocyanate. As the acryl-based polymer, one obtained by copolymerizing the hydroxy group-containing monomers described previously as an example, ether-based compounds such as 2-hydroxyethyl vinyl ether, 4-hydroxybutyl vinyl ether and diethylene glycol monovinyl ether, and so on is used.

For the intrinsic ultraviolet-ray curing-type pressure-sensitive adhesive, the base polymer (particularly acryl-based polymer) having a carbon-carbon double bond can be used alone, but the ultraviolet-ray curable monomer component or oligomer component within the bounds of not deteriorating properties can also be blended. The amount of the ultraviolet-ray curable oligomer component or the like is normally within a range of 30 parts by weight or less, preferably in a range of 0 to 10 parts by weight, based on 100 parts by weight of the base polymer.

A photopolymerization initiator is included in the ultraviolet-ray curing-type pressure-sensitive adhesive when it is cured by ultraviolet rays or the like. Examples of the photopolymerization initiator include a-ketol-based compounds such as 4-(2-hydroxyethoxy)phenyl(2-hydroxy-2-propyl)ketone, α-hydroxy-α,α′-dimethylacetophenone, 2-methyl-2-hydroxypropiophenone and 1-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morphorinopropane-1; benzoin ether-based compounds such as benzoin ethyl ether, benzoin isopropyl ether and anisoin methyl ether; ketal-based compounds such as benzyldimethylketal; aromatic sulfonyl chloride-based compounds such as 2-naphthalenesulfonyl chloride; photoactive oxime-based compounds such as 1-phenyl-1,2-propanedione-2-(O-ethoxycarbonyl)oxime; benzophenone-based compounds such as benzophenone, benzoyl benzoic acid and 3,3′-dimethyl-4-methoxybenzophenone; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone and 2,4-diisopropylthioxanthone; camphorquinone; halogenated ketone; acylphosphinoxide; and acylphosphonate. The blending amount of the photopolymerization initiator is, for example, about 0.05 to 20 parts by weight based on 100 parts by weight of the base polymer such as an acryl-based polymer which forms a pressure-sensitive adhesive.

Examples of the ultraviolet-ray curing-type pressure-sensitive adhesive include rubber-based pressure-sensitive adhesives and acryl-based pressure-sensitive adhesives disclosed in JP-A-60-196956, which contain a photopolymerizable compound such as an addition-polymerizable compound having two or more unsaturated bonds, or alkoxysilane having epoxy group, and a photopolymerization initiator such as a carbonyl compound, an organic sulfur compound, a peroxide, an amine or an onium salt-based compound.

When curing hindrance by oxygen occurs at the time of irradiation of ultraviolet rays, it is desirable to block oxygen (air) from the surface of the ultraviolet-ray curing-type pressure-sensitive adhesive layer 8. Examples of the method thereof include a method in which the surface of the pressure-sensitive adhesive layer 8 is covered with a separator, and a method in which irradiation of ultraviolet rays or the like is carried out in a nitrogen gas atmosphere.

The thickness of the pressure-sensitive adhesive layer 8 is not particularly limited, but is preferably about 1 to 50 μm from the viewpoint of compatibility of prevention of chipping of a chip cut surface, fixation and retention of the under-fill material, and so on. The thickness is preferably 2 to 30 μm, more preferably 5 to 25 μm.

### (Method for Producing a Sealing Sheet)

Aspects different from the method for producing a sealing sheet in the first embodiment will be described below. First, the method for preparing the base material 1 is same as that in the first embodiment, and therefore is not described here.

Next, a pressure-sensitive adhesive composition for formation of a pressure-sensitive adhesive layer is prepared. Resins and additives as described in the term of the pressure-sensitive adhesive layer, and so on are blended in the pressure-sensitive adhesive composition. The prepared pressure-sensitive adhesive composition is applied onto the base material 1 to form a coating film, and the coating film is then dried (crosslinked by heating as necessary) under predetermined conditions to form the pressure-sensitive adhesive layer 8. The coating method is not particularly limited, and examples thereof include roll coating, screen coating and gravure coating. For drying conditions, for example, the drying temperature is in a range of 80 to 150° C., and the drying time is in a range of 0.5 to 5 minutes. The pressure-sensitive adhesive layer 8 may be formed by applying a pressure-sensitive adhesive composition onto a separator to form a coating film, followed by drying the coating film under the aforementioned conditions. Thereafter, the pressure-sensitive adhesive layer 8 is bonded onto the base material 1 together with the separator. As a member with a pressure-sensitive adhesive layer formed on a base material as described above, a commercially available film for dicing may be used.

On the other hand, an under-fill material formed on a release film (separator) is prepared in the same manner as in the first embodiment. Then, the under-fill material and the pressure-sensitive adhesive layer are bonded together such that they form a bonding surface. Bonding can be performed by, for example, heat pressure-bonding. At this time, the lamination temperature is not particularly limited and is, for example, preferably 30 to 80° C., more preferably 40 to 60° C. The linear pressure is not particularly limited and is, for example, preferably 0.1 to 20 kgf/cm (0.98 to 196 N/cm), more preferably 1 to 10 kgf/cm (9.8 to 98 N/cm). In this way, the sealing sheet according to the third embodiment can be prepared.

Even with the sealing sheet according to the third embodiment, a semiconductor device can be produced basically in the same manner as in the first embodiment. However, the pickup step is carried out after the pressure-sensitive adhesive layer 8 is irradiated with ultraviolet rays when the pressure-sensitive adhesive layer 8 is of an ultraviolet-ray curing-type. Consequently, the adhesive strength of the pressure-sensitive adhesive layer 8 to the under-fill material 2 decreases, so that it becomes easy to peel off the semiconductor chip 5 with the under-fill material 2. As a result, pickup is possible without damaging the semiconductor chip 5. Conditions such as the irradiation intensity and the irradiation time at the time of irradiation of ultraviolet rays are not particularly limited, and may be appropriately set as necessary. When the pressure-sensitive adhesive layer 8 is irradiated with ultraviolet rays to be cured beforehand, and the cured pressure-sensitive adhesive layer 8 and the under-fill material 2 are bonded, irradiation of ultraviolet rays here is not required.

### EXAMPLES

Preferred Examples of the present invention will be illustratively described in detail below. However, for the materials, the blending amounts, and so on described in Examples, the scope of the present invention is not intended to be limited thereto unless definitely specified. The part(s) means “part(s) by weight”.

### <Examples According to First Embodiment>

Following Examples and so on correspond to a method for producing a semiconductor device according to the first embodiment.

### Example 1

### Preparation of Sealing Sheet)

56 parts of an epoxy resin 1 (trade name: “Epicoat 1004” manufactured by JER Corporation), 19 parts of an epoxy resin 2 (trade name: “Epicoat 828” manufactured by JER Corporation), 75 parts of a phenol resin (trade name “Mirex XLC-4L” manufactured by Mitsui Chemicals, Incorporated), 167 parts of spherical silica (trade name “SO-25R” manufactured by Admatechs), 1.3 parts of an organic acid (trade name “Orthoanisic Acid” manufactured by Tokyo Chemical Industry Co., Ltd.) and 1.3 parts of an imidazole catalyst (trade name “2PHZ-PW” manufactured by Shikoku Chemicals Corporation) based on 100 parts of an acrylic acid ester-based polymer including acrylic acid ethyl-methyl methacrylate as its main component (trade name “Paraclone W-197CM” manufactured by Negami Chemical Industrial Co., Ltd.) were dissolved in ethyl methyl ketone to prepare an adhesive composition solution having a solid concentration of 23.6% by weight.

The adhesive composition solution was applied onto a release-treated film made of a silicone release-treated polyethylene terephthalate film having a thickness of 50 μm as a base material, and dried at 130° C. for 2 minutes to thereby prepare a sealing sheet with an under-fill material having a thickness of 45 μm provided on a base material.

### (Preparation of Semiconductor Device)

A silicon wafer with bumps on one surface, in which bumps were formed on one surface, was provided, and the prepared sealing sheet was bonded to a surface on which the bumps of the silicon wafer with bumps on one surface was formed with the under-fill material as a bonding surface. As the silicon wafer with bumps on one surface, the following article was used. Bonding conditions were as follows. The ratio of the thickness Y (=45 μm) of the under-fill material to the height X (=45 μm) of a connection member (Y/X) was 1.

<Silicon Wafer with Bumps on One Surface>
Diameter of silicon wafer: 8 inches
Thickness of silicon wafer: 0.2 mm (200 μm)
Height of bump: 45 μm
Pitch of bump: 50 μm
Material of bump: solder

<Bonding Conditions>

Bonding device: trade name “DSA 840-WS” manufactured by NITTO SEIKI CO., Ltd.
Bonding speed: 5 mm/min
Bonding pressure: 0.25 MPa
Stage temperature at the time of bonding: 80° C.
Degree of vacuum at the time of bonding: 150 Pa

The silicon wafer with bumps on one surface and the sealing sheet were bonded together in accordance with the above-mentioned procedure, and dicing was then performed under the following conditions. Dicing was performed by full cut so as to have a chip size of 7.3 mm×7.3 mm.

<Dicing Conditions>

Dicing device: trade name “DFD-6361” manufactured by DISCO Corporation
Dicing ring: “2-8-1” (manufactured by DISCO Corporation)
Dicing speed: 30 mm/sec

### Dicing Blade:

Z1; “203O-SE 27HCDD” manufactured by DISCO Corporation
Z2; “2030-SE 27HCBB” manufactured by DISCO Corporation

### Dicing Blade Rotation Number:

### Z1; 40000 rpm

### Z2; 45000 rpm

Cut mode: step cut
Wafer chip size: 7.3 mm×7.3 mm

Next, a laminate of an under-fill material and a semiconductor chip with bumps on one surface was picked up by a method of push-up by a needle from the base material side of each sealing sheet. Pickup conditions were as follows.

### <Pickup Conditions>

Pickup device: trade name “SPA-300” manufactured by SHINKAWA LTD. The number of needles: 9Needle push-up amount: 500 μm (0.5 mm) Needle
push-up speed: 20 mm/second
Pickup time: 1 secondExpanding amount: 3 mm

Subsequently, The picked-up laminate was retained under the following heating conditions.

<Heating Conditions>

Pickup device: trade name “FCB-3” manufactured by Panasonic Corporation
Heating condition: 150° C.×2 seconds

Finally, the semiconductor chip was mounted by heat pressure-bonding the semiconductor chip to a BGA substrate under the following heat pressure-bonding conditions in the state that the bump forming surface of the semiconductor chip and the BGA substrate were made to face to each other. Consequently, a semiconductor device with a semiconductor chip mounted on a BGA substrate was obtained. In this step, a two-stage process of performing heat pressure-bonding under the heat pressure-bonding condition 1 and then under the heat pressure-bonding condition 2 was carried out.

<Heat Pressure-Bonding Condition 1>

Pickup device: trade name “FCB-3” manufactured by Panasonic Corporation
Heating temperature: 150° C.

### Load: 98 N

Retention time: 10 seconds
<Heat pressure-bonding condition 2>
Pickup device: trade name “FCB-3” manufactured by Panasonic Corporation
Heating temperature: 260° C.

### Load: 98 N

Retention time: 10 seconds

### Example 2

A semiconductor device was prepared in the same manner as in Example 1 except that a laminate of a semiconductor element and an under-fill material was retained under the following heating conditions.

<Heating Conditions>

Pickup device: trade name “FCB-3” manufactured by Panasonic Corporation
Heating condition: 100° C.×2 seconds

### Example 3

A semiconductor device was prepared in the same manner as in Example 1 except that a laminate of a semiconductor element and an under-fill material was retained under the following heating conditions.

<Heating Conditions>

Pickup device: trade name “FCB-3” manufactured by Panasonic Corporation
Heating condition: 200° C.×2 seconds

### Example 4

A semiconductor device was prepared in the same manner as in Example 1 except that a laminate of a semiconductor element and an under-fill material was retained under the following heating conditions.

<Heating Conditions>

Pickup device: trade name “FCB-3” manufactured by Panasonic Corporation
Heating condition: 150° C.×1 second

### Example 5

A semiconductor device was prepared in the same manner as in Example 1 except that a laminate of a semiconductor element and an under-fill material was retained under the following heating conditions.

<Heating Conditions>

Pickup device: trade name “FCB-3” manufactured by Panasonic Corporation
Heating condition: 100° C.×1 second

### Example 6

A semiconductor device was prepared in the same manner as in Example 1 except that a laminate of a semiconductor element and an under-fill material was retained under the following heating conditions.

<Heating Conditions>

Pickup device: trade name “FCB-3” manufactured by Panasonic Corporation
Heating condition: 200° C.×1 second

### Comparative Example 1

A semiconductor device was prepared in the same manner as in Example 1 except that a laminate of a semiconductor element and an under-fill material was retained under the following heating conditions.

<Heating Conditions>

Pickup device: trade name “FCB-3” manufactured by Panasonic Corporation
Heating condition: 50° C.×2 seconds

### Comparative Example 2

A semiconductor device was prepared in the same manner as in Example 1 except that a laminate of a semiconductor element and an under-fill material was retained under the following heating conditions.

<Heating Conditions>

Pickup device: trade name “FCB-3” manufactured by Panasonic Corporation

Heating condition: 250° C.×2 seconds

### Comparative Example 3

A semiconductor device was prepared in the same manner as in Example 1 except that a step of retaining a laminate of a semiconductor element and an under-fill material was not provided.

### (Measurement of Minimum Melt Viscosity)

The minimum melt viscosity of an under-fill material (before heat curing) was measured. The measurement of the minimum melt viscosity was a value measured by a parallel plate method using a rheometer (RS-1 manufactured by HAAKE, INC.). More specifically, the melt viscosity was measured in a range from 60° C. to 200° C. under conditions of gap: 100 μm; rotation corn diameter: 20 mm; rotation speed: 10 s⁻¹; and temperature rise rate: 10° C./minute, and the minimum value of melt viscosities in a range from 100° C. to 200° C. obtained at this time was designated as a minimum melt viscosity. The results are shown in Table 1.

### (Evaluation for Generation of Voids)

An evaluation for generation of voids was performed in such a manner that the semiconductor device prepared in each of Examples and Comparative Examples was cut between the under-fill material and the BGA substrate, the cut surface was observed using an image recognition device (trade name “C9597-11” manufactured by Hamamatsu Photonics K.K.), and a ratio of the total area of void portions to the area of the semiconductor chip was calculated. The ratio of the total area of void portions to the area of the semiconductor chip in the observed image of the cut surface was determined, and “◯” was assigned when the ratio was 0 to 5%, “Δ” was assigned when the ratio was more than 5% and equal to or less than 25%, and “x” was assigned when the ratio was more than 25%. The results are shown in Table 1.

TABLE 1

| | Example | Example | Example | Example | Example | Example | Comparative | Comparative | Comparative |
|---|---|---|---|---|---|---|---|---|---|
| | 1 | 2 | 3 | 4 | 5 | 6 | Example 1 | Example 2 | Example 3 |
| Heating | 150 | 100 | 200 | 150 | 100 | 200 | 50 | 250 | — |
| temperature | | | | | | | | | |
| in retention | | | | | | | | | |
| step [° C.] | | | | | | | | | |
| Retention | 2 | 2 | 2 | 1 | 1 | 1 | 2 | 2 | 0 |
| time in | | | | | | | | | |
| retention | | | | | | | | | |
| step | | | | | | | | | |
| [seconds] | | | | | | | | | |
| Minimum melt | 5320 | 5320 | 5320 | 5320 | 5320 | 5320 | 5320 | 5320 | 5320 |
| viscosity | | | | | | | | | |
| [Pa · s] | | | | | | | | | |
| Evaluation | ∘ | ∘ | ∘ | ∘ | ∘ | ∘ | Δ | x | x |
| for | | | | | | | | | |
| generation | | | | | | | | | |
| of voids | | | | | | | | | |

As apparent from Table 1, generation of voids was suppressed in the semiconductor devices according to Examples. On the other hand, voids were generated in the semiconductor devices according to Comparative Examples 1 to 3. For Comparative Example 1, it is considered that since the retention temperature was lower than 100° C., moisture in the under-fill material was not sufficiently removed, and moisture was vaporized by heating during mounting of the semiconductor element, resulting in generation of voids. For Comparative Example 2, it is considered that since the retention temperature was higher than 200° C., moisture in the under-fill material was rapidly vaporized, resulting in generation of voids. For Comparative Example 3, it is considered that since a retention step was not provided, moisture in the under-fill material was not removed, resulting in generation of voids. Thus, it is apparent that by providing a step of retaining a semiconductor element with an under-fill material at 100 to 200° C. for 1 second or more as a process for producing a semiconductor device, a high-reliability semiconductor device in which generation of voids is suppressed can be produced.

### <Examples According to Second Embodiment>

Following Examples and so on correspond to a method for producing a semiconductor device according to the second embodiment.

### Example 1

Preparation of a sealing sheet up to pickup of a laminate of an under-fill material and a semiconductor chip with bumps on one surface were carried out in the same manner as in Example 1 according to the first embodiment, and finally a contact step and a fixation step of a connection step were carried out under each of the following heat pressure-bonding conditions 1 and 2, so that the semiconductor chip was thermally compressed to a BGA substrate in the state that the bump forming surface of the semiconductor chip and the BGA substrate were made to face to each other, thereby performing electrical connection between the semiconductor chip and the BGA substrate. Consequently, a semiconductor device with a semiconductor chip mounted on a BGA substrate was obtained.

<Heat Pressure-Bonding Condition 1>

Pickup device: trade name “FCB-3” manufactured by Panasonic Corporation
Heating temperature: 150° C.

### Load: 98 N

Retention time: 10 seconds

<Heat Pressure-Bonding Condition 2>

Pickup device: trade name “FCB-3” manufactured by Panasonic Corporation
Heating temperature: 260° C.

### Load: 98 N

Retention time: 10 seconds

### Example 2

A semiconductor device was prepared in the same manner as in Example 1 except that a connection step was carried out under the following heat pressure-bonding conditions.

<Heat Pressure-Bonding Condition 1>

Pickup device: trade name “FCB-3” manufactured by Panasonic Corporation
Heating temperature: 121° C.

### Load: 98 N

Retention time: 10 seconds

<Heat Pressure-Bonding Condition 2>

Pickup device: trade name “FCB-3” manufactured by Panasonic Corporation
Heating temperature: 260° C.

### Load: 98 N

Retention time: 10 seconds

### Example 3

A semiconductor device was prepared in the same manner as in Example 1 except that a connection step was carried out under the following heat pressure-bonding conditions.

### <Heat Pressure-Bonding Condition 1>

Pickup device: trade name “FCB-3” manufactured by Panasonic Corporation
Heating temperature: 150° C.

### Load: 98 N

Retention time: 10 seconds

<Heat Pressure-Bonding Condition 2>

Pickup device: trade name “FCB-3” manufactured by Panasonic Corporation
Heating temperature: 321° C.

### Load: 98 N

Retention time: 10 seconds

### Comparative Example 1

A semiconductor device was prepared in the same manner as in Example 1 except that a connection step was carried out under the following heat pressure-bonding conditions.

<Heat Pressure-Bonding Condition 1>

Pickup device: trade name “FCB-3” manufactured by Panasonic Corporation
Heating temperature: 50° C.

### Load: 98 N

Retention time: 10 seconds

<Heat Pressure-Bonding Condition 2>

Pickup device: trade name “FCB-3” manufactured by Panasonic Corporation
Heating temperature: 260° C.

### Load: 98 N

Retention time: 10 seconds

### Comparative Example 2

A semiconductor device was prepared in the same manner as in Example 1 except that a connection step was carried out under the following heat pressure-bonding conditions.

<Heat Pressure-Bonding Condition 1>

Pickup device: trade name “FCB-3” manufactured by Panasonic Corporation
Heating temperature: 240° C.

### Load: 98 N

Retention time: 10 seconds

<Heat Pressure-Bonding Condition 2>

Pickup device: trade name “FCB-3” manufactured by Panasonic Corporation
Heating temperature: 260° C.

### Load: 98 N

Retention time: 10 seconds

### Comparative Example 3

A semiconductor device was prepared in the same manner as in Example 1 except that a connection step was carried out in a batch under the following heat pressure-bonding conditions without separating the connection step into a contact step and a fixation step.

<Heat Pressure-Bonding Conditions>

Pickup device: trade name “FCB-3” manufactured by Panasonic Corporation
Heating temperature: 260° C.

### Load: 98 N

Retention time: 30 seconds

### (Measurement of Minimum Melt Viscosity)

The minimum melt viscosity of an under-fill material (before heat curing) was measured. The measurement of the minimum melt viscosity was a value measured by a parallel plate method using a rheometer (RS-1 manufactured by HAAKE, INC.). More specifically, the melt viscosity was measured in a range from 100° C. to 230° C. under conditions of gap: 100 μm; rotation corn diameter: 20 mm; rotation speed: 10 s⁻¹; and temperature rise rate: 10° C./minute, and the minimum value of melt viscosities obtained at this time was designated as a minimum melt viscosity. The results are shown in Table 2.

### (Evaluation of Connectivity)

An evaluation of electronic connection between the semiconductor element and the BGA substrate was made in such a manner that conduction was checked using Digital Multi-Meter TR 6847 (manufactured by ADVANTEST CORPORATION) for 10 samples of the semiconductor devices prepared in Examples and Comparative Examples, the ratio of samples, for which conduction was observed, was determined, and “◯” was assigned when the ratio was 90% or more, and “x” was assigned when the ratio was less than 90%. The results are shown in Table 2.

TABLE 2

| | Example | Example | Example | Comparative | Comparative | Comparative |
|---|---|---|---|---|---|---|
| | 1 | 2 | 3 | Example 1 | Example 2 | Example 3 |
| Heating | 150 | 121 | 150 | 50 | 240 | 260° C. |
| temperature | | | | | | (in batch) |
| in contact | | | | | | |
| step [° C.] | | | | | | |
| Heating | 260 | 260 | 321 | 260 | 260 | |
| temperature | | | | | | |
| in fixation | | | | | | |
| step [° C.] | | | | | | |
| Minimum melt | 5320 | 5320 | 5320 | 5320 | 5320 | 5320 |
| viscosity | | | | | | |
| [Pa · s] | | | | | | |
| Evaluation of | ∘ | ∘ | ∘ | x | x | x |
| connectivity | | | | | | |

As apparent from Table 2, satisfactory conduction was observed in the semiconductor devices according to Examples. On the other hand, in Comparative examples 1 to 3, there were many samples, for which a conduction state was not observed, and connection reliability was low. For comparative Example 1, it is considered that since the heating temperature in the contact step (heat pressure-bonding condition 1) was lower than (melting point of bump −100° C.), the under-fill material was not sufficiently softened, and thus contact between the bump and the substrate was inadequate. For Comparative Examples 2 and 3, it is considered that since the heating temperature in the contact step was higher than the melting point of the bump, melting of the metal started before the under-fill material between the substrate and the bump was sufficiently pushed aside, so that the under-fill material remained between the bump and the substrate, resulting in inadequate contact. Thus, it is apparent that a high-reliability semiconductor device can be produced by providing a connection step, which has a contact step satisfying the predefined requirement (1) and a fixation step satisfying the predefined requirement (2), as a process for producing a semiconductor device.

What is claimed is:

1. A method for producing a semiconductor device having an adherend, a semiconductor element electrically connected to the adherend, and an under-fill material for filling a space between the adherend and the semiconductor element, wherein the method comprises:
a providing step of providing a sealing sheet having a base material and an under-fill material laminated on the base material;
a bonding step of bonding the sealing sheet to a surface of a semiconductor wafer on which a connection member is formed;
a dicing step of dicing the semiconductor wafer to form a semiconductor element with the under-fill material;
a retention step of retaining the semiconductor element with the under-fill material at 100 to 200° C. for 1 second or more; and
a connection step of electrically connecting the semiconductor element and the adherend through the connection member while filling a space between the adherend and the semiconductor element using the under-fill material.

2. The method for producing a semiconductor device according to claim 1, wherein the minimum melt viscosity of the under-fill material at 100 to 200° C. before heat curing is 100 Pa·s or more and 20000 Pa·s or less.

3. The method for producing a semiconductor device according to claim 1, wherein the viscosity of the under-fill material at 23° C. before heat curing is 0.01 MPa·s or more and 100 MPa·s or less.

4. The method for producing a semiconductor device according to claim 1, wherein the water absorption rate of the under-fill material under conditions of temperature: 23° C. and humidity: 70% before heat curing is 1% by weight or less.
